(19) United States
(12) Patent Application Publication
(10) Pub. No.: US 2015/0040983 A1
(43) Pub. Date: Feb. 12, 2015

(54) ACIDIC ETCHING PROCESS FOR SI WAFERS

(71) Applicant: SolarWorld Industries America, Inc., Hillsboro, OR (US)

(72) Inventor: Konstantin Holdermann, Hillsboro, OR (US)

(73) Assignee: SolarWorld Industries America, Inc., Hillsboro, OR (US)

(21) Appl. No.: 13/960,876

(22) Filed: Aug. 7, 2013

(51) Int. Cl. H01L 21/02; H01L 31/028

(52) U.S. Cl. CPC H01L 21/02019; H01L 31/028
USPC 136/261; 438/745; 438/694; 438/542; 257/620

(57) ABSTRACT

The present invention relates to a method for acidic surface etching of a silicon wafer, such as those used for solar cells, comprising contacting at least one surface of a silicon wafer as cut with an acidic etching agent, provided that the wafer is, prior to the acidic etching, not subjected to an alkaline etching step or process. Further, the present invention is directed to Si wafer, photovoltaic cells, PERC photovoltaic cells and solar modules produced according to the method of the present invention.

### FIELD OF THE INVENTION

The present invention relates to a method for acidic surface etching of a silicon wafer, such as those used for solar cells, comprising contacting at least one surface of a pre-cleaned silicon wafer with an acidic etching agent. Further, the present invention is directed to a silicon wafer produced according to the method of the present invention and solar modules containing the same.

### BACKGROUND OF THE INVENTION

Cut Si wafers are contaminated by metal, e.g. copper and iron. Slurry cut wafers usually contain a higher metal contamination than diamond wire sawed wafers. In a first cleaning step (Pre-Clean) the wafers have to be released from epoxy-strips (glue) that also takes away the main part of the slurry from the wafer surface together with parts of the metallic contaminants. Dependent from the glue type this cleaning process runs with hot water in combination with surfactant or without surfactant supported by ultrasonic. Common is also the usage of organic acid, like diluted acetic acid, lactic acid or oxalate acid to improve the glue release, and to lower the metallic contaminants. The thus pre-cleaned wafers are still saw-damaged, and prior to the alkaline etching process they need to be cleaned further. The saw damaged surface still contains trapped metallic contaminants and organic residues, e.g. glue stains, fingerprints. It is known, that the homogeneity of either an alkaline damage etched surface or an alkaline texture etched surface depends strongly from the quality of an organic free wafer surface. The industrial production of high efficiency cells therefore uses additional either an ozone or hydrogen-peroxide cleaning process often combined with an additional surfactant process as a second cleaning step (final clean) in front of the alkaline damage etch process or the alkaline texture etch process. To avoid that dragged over traces of copper will plate out on the wafer surface in the cleaning process following any alkaline etching process, it is state of the arte to use additional ozone or hydrogen peroxide in the HF bath.

To begin the etching process of mono crystalline wafer or quasi mono crystalline wafer with an acidic etching step instead of any alkaline etching step simplifies the cleaning request on the cut wafers. For the event that the pre-clean process is sufficient enough, no additional “final clean” with ozone or hydrogen peroxide is required. Therefore less intense cleaned wafers can be processed due to the “robust” etching process. This step even allows using low grade (industrial grade) nitric acid and fluoric acid as etching mixture, what makes this process cost comparable to the alkaline etching process. Efficiencies of over 19.5% are achievable. The usage of acidic etching in-line tools helps additional to lower the maintenance costs and to increase the throughput compared to the alkaline batch process.

The acidic etching process can be selected as a 2 side etching process, where the wafer will be submerged processed, like state of the art for multi (poly) crystalline wafers. Also it is possible to combine the 2 side etching step with an 1 side etching step, or even to run only a 1 side etching process, similar to the edge isolation process, but with higher etch removal of up to 8 μm. The alkaline texture etching process follows then the acidic etch step, after the rear side is passivated by SiO₂/SiNₓ or Al₂O₃/SiNₓ. It doesn't matter if the alkaline texture process happens by a batch process or in-line process. In both cases only the wafer front side will be texture etched while the passivation layer protects the rear side.

Also it is possible to do first the rear side pattering of the passivation stack by laser, followed by the alkaline texture etch process (see FIG. 1 and FIG. 5). This way the ablated locations on the rear side will be texture etched together with the front side without adding any additional process step. This change in the process sequence is helpful to correct uncompleted laser spots especially close to the wafer edges reducing this way interrupted openings The increased surface roughness of the textured structure increases additional the Al-metallization contact that should improve the alloying formation.

The achievable surface can be rougher than the typical polished surface achievable after the alkaline damage etching process. Surprisingly even the rougher surface keeps the passivation quality of the SiO₂/SiNₓ passivation stack that is known to be more sensitive than the Al₂O₃/SiNₓ passivation stack regarding the surface smoothness; refer to “Impact of the rear surface roughness on industrial-type PERC Solar Cells” by C. Kranz et al. Obviously not only the smoothness of the surface but also the achieved surface structure (texture) is an important key factor too. High concentrated concave horizontal grooves, typically for the acidic texture etching of multi wafers for example seem to have a negative effect for the passivation layer itself, and might to be more challenging in the combination with laser ablation as next following process step.

Further, when charge carriers are generated in a photovoltaic cell and subsequently the charge carriers shall be converted into electricity, compositions are necessary that provide the front surface of the wafer with properties that increase light absorbance like pyramidal texture, combined with selective emitter and AR-layer, and compositions that lowers the recombination of the generated charge carriers, like front side passivation and back side passivation.

Commonly known PERC (passivated emitter and rear contacts) photovoltaic cells comprise passivation layers in order to increase lifetime of the generated charge carriers by reducing their recombination, and provide on the rear side a BSF, e.g. with aluminum, that is located only in areas where a laser removed parts of the passivation layer. The patterned local BSF provides enough rear side contact without reducing the rear side passivation significantly.

As described in the Centaurus process (refer to DE 102010054370 A1) the alkaline damage etching process combined with an additional HF-ozone cleaning step provides a polished and clean surface required for the SiO₂/SiNₓ passivation stack. The alkaline front side texture etching then happens after the rear side passivation process, using the passivation stack as mask to protect the rear side. Known alternative PERC-process starting with an alkaline texture etching step, followed by an acidic single side etching step. The passivation stack, e.g. Al₂O₃/SiNₓ or SiO₂/SiNₓ, is then generated on the rear side of the Si wafer in the next step.

### SUMMARY OF THE INVENTION

The present invention is based on the inventor's surprising finding that by contacting at least one surface of a Si wafer as cut with an acidic etching agent metallic and organic contaminants originating from the prior saw process are efficiently removed and the surface roughness can be controlled. ICP-MS results of the acidic etched wafers presented significant lower Cu findings compared to alkaline etched wafers. This result is important regarding the cell degradation. In addition, it has been found that such an etching process obviates the need for extensive cleaning prior to and after the etching step. Accordingly, the present invention allows a fast, cost-efficient process due to less cleaning steps and usage of low grade chemicals for the acidic etching process. Further, the present invention allows to finely tune the amount of roughness of the surface structure of the Si wafer, thus optimizing effectiveness of the passivation layer.

Accordingly, the same result as in the above-referenced Centaurus process can be achieved alternatively starting with an acidic damage etching process without any ozone or hydrogen peroxide. Selecting for the wafer as cut the acidic single side etching process, followed by the texture etch process after the rear side passivation, reduces the total etch removal by 5-10 μm. This is actually possible only in this etching combination, acidic-alkaline, but not in the combination alkaline-acidic, because the alkaline etching process of wafers as cut affects from begin both sides of the wafer, no matter if it is run in a batch tool or inline tool. The gain in less etch removal is an advantage that helps to improve the production yield as the wafers are cut thinner and thinner.

In a first aspect, the present invention is therefore directed to a method for acidic etching a Si wafer comprising contacting at least one surface of a Si wafer as cut with an acidic etching agent, with the proviso that the Si wafer is, prior to the acidic etching, not subjected to an alkaline etching step or process.

In a second aspect, the present invention relates to Si wafers obtained according to the claimed method and solar modules comprising the same.

### BRIEF DISCRIPTION OF THE FIGURES

FIG. 1 is a schematic illustration of a monoPERC process according to the present invention.

FIG. 2 shows a scanning electron microscopy (SEM) image of a surface of the rear side (upper picture) of a Si wafer as cut after acidic etching with nitric acid (67.5 wt.-% in water) and hydrofluoric acid (49 wt.-% in water) mixed 6.5/1 (v/v) for 3 minutes at 15° C., and 9.5 μm Si removal. The lower SEM image shows a surface of the front side of a Si wafer as cut after the acidic etching under the same etching conditions. See example 2 below.

FIG. 3 shows a SEM image of a surface of the rear side of a Si wafer as cut after the acidic etching with nitric acid (69.5 wt.-% in water) and hydrofluoric acid (49 wt.-% in water) mixed 9.0/1 (v/v) for 3 minutes at 12 ° C., and 7 μm Si removal. See example 3 below.

FIG. 4 shows a SEM image of the rear side of an insufficiently cleaned stained wafer after the acidic etching process. See example 4 below.

FIG. 5 shows 2 SEM of the texture etched opened structure of the wafer rear-side, by running the alkaline texture etch process after the laser ablation process. This is a possible change in process sequence of the monoperc process, using acidic etching step first but the alkaline texture process several process steps later.

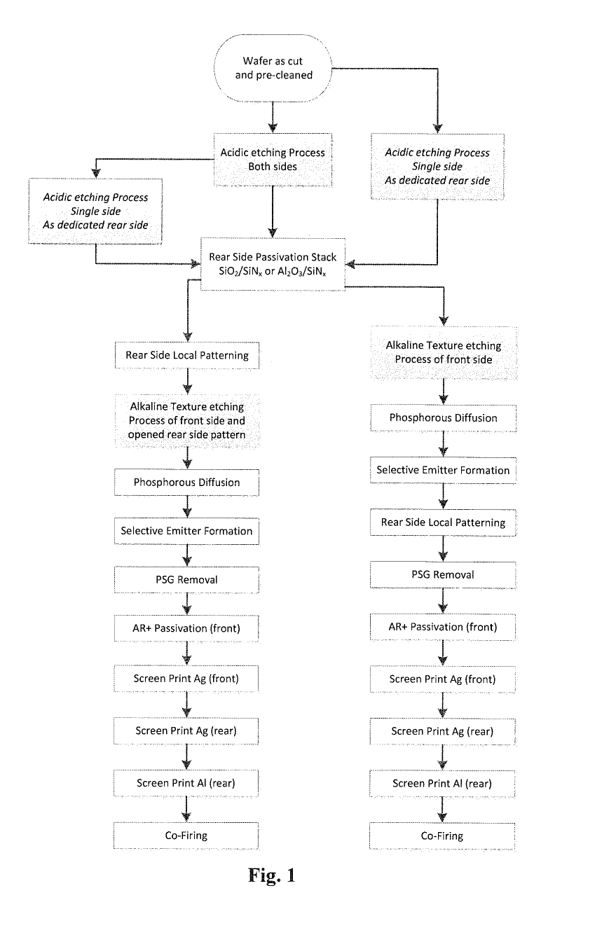

### DETAILED DESCRIPTION OF THE INVENTION

In the context of the various embodiments, the following terms have the meaning indicated below unless explicitly indicated otherwise.

The term “acidic etching agent” as used herein refers to chemical compositions, preferably aqueous solutions of an acidic agent with a H₃O⁺ concentration higher than 1 mol/L, that contains at least nitric acid as oxidizing agent and additional fluoride to dissolve the oxidized silicon.

The term “pre-cleaned” as used herein refers to a saw-damaged wafer as cut, which has been pre-cleaned with hot water in combination with surfactant or without surfactant supported by ultrasound. Alternatively, said wafer has been pre-cleaned with organic acid, like diluted acetic acid, lactic acid or oxalic acid to improve the glue release, and to lower metallic contaminants.

The term “saw-damaged” as used herein refers to a Si wafer which is surface damaged by the sawing and/or contaminated by, for example, metals or organic residues originating from the saw process.

The term “aqueous solution” as used herein refers to a water based solution.

Various embodiments are based on the inventor's finding that etching at least one surface of a Si wafer as cut with an acidic etching agent without subjecting the Si wafer to an alkaline etching step or process will obviate the need for extensive cleaning of the Si wafer surface before and after the etching, in particular after the etching. The acidic etching process according to the present invention removes metal contamination, e.g. copper and iron, and organic stains, e.g. glue stains, originating from the sawing of the wafer. Accordingly, the present invention allows for a fast, cost-efficient process due to obviating the need for extensive cleaning steps. Additionally, the surface roughness of the wafer surface can be controlled by varying the acidic etching agent and the contacting conditions. Therefore, the present invention allows controlling of the roughness of the surface structure of the Si wafer and thus optimizing said structure for a good rear side laser ablation process on one hand and a good passivation layer on the other hand.

In various embodiments the Si wafer is a monocrystalline Si wafer or a quasi-monocrystalline Si wafer.

In a further embodiment the Si wafer is saw-damaged and/or cleaned prior to etching.

In another embodiment the acidic etching agent is a mixture of hydrofluoric acid and nitric acid.

In a specific embodiment of the present invention the acidic etching agent is an aqueous solution containing a mixture of acetic acid, nitric acid and hydrofluoric acid. In another embodiment the acidic etching agent comprises AcOH (98 wt.-% in water), HNO₃ (69 wt.-% in water), and HF (49 wt.-% in water), with the volume ratio of AcOH:HNO₃:HF being 10:6:4.

In another embodiment the acidic etching agent is an aqueous solution containing a mixture of HNO₃ and HF. In another embodiment the acidic etching agent comprises HNO₃ (69 wt.-% in water) and HF (49 wt.-% in water), wherein the volume ratio of HNO₃:HF is 8:1.

The chemicals used in the acidic etching of a Si wafer of the present invention are commercially available, low-priced due to the possibility to use low grade acid, like technical grade or industrial grade. In various embodiments, the acidic etching agent may further contain at least one additive, for example surfactants and/or stabilizers. The surfactant may be selected from the group comprising but not limited to sulfonic acids, stable anionic surfactant and the like.

The etching solutions of various embodiments may further include one or more auxiliaries which are known to those skilled in the art. Exemplary auxiliaries may include but are not limited to viscosity-controlling agents like sulfuric acid and phosphorous acid. Further auxiliaries that may be used to influence the NOₓ bubbles on the wafer down side s are gaseous agents, such as air, oxygen, nitrogen and ozone that are finely dispersed in the acidic etching agent containing solution. Injecting of ozone or dosing of hydrogen peroxide also affects the balance of nitrous gases due to their oxidizing character.

In various embodiments of the present invention, the contacting of the at least one surface of a Si wafer as cut with the acidic etching agent may include spraying or to wet it by printing the acidic etching agent onto the Si wafer or dipping the wafer into the acidic etching agent or coating the Si wafer with acidic etching agent. In a further embodiment the Si wafer is dipped as a whole into the acidic etching agent. The contacting may be achieved by all suitable methods well known to those skilled in the art.

In various embodiments of this process, the acidic etching agent is stirred, circulated or agitated, for example by a stirrer, ultrasonifier, shaker or pump. This may facilitate the diffusion of the etching agents to the wafer surface and the diffusion of reaction products away from the wafer surface.

In further embodiments the contacting time of the acidic etching agent with the Si wafer surface may be in the range of a few seconds to hours, preferably from 0.5-30 minutes and more preferably from 1-10 minutes.

The contacting may occur at a temperature from 5-45° C., preferably from 8-40° C. and more preferably at a temperature from 10-35° C. The acidic etching agent may be heated to the desired temperature.

In various embodiments the etching process can be conducted on one surface of the Si wafer or on two surfaces of the same Si wafer. For example, it is possible to only subject the later rear side of the wafer or, alternatively, both, the later front and rear side of the wafer to the present acidic etching process.

A combined acidic etching of first both sides then one side is beneficial to avoid bowing of the wafer as cut at the acidic single etch process. Only less than 3.0 μm, preferable 0.2-1.5 μm, and more preferably 0.3-1.0 μm in total needs to be removed prior to the acidic single etch process to avoid bowed wafers. Other helpful strategies are the usage of top rollers of higher density (weight), typically fluoropolymers, e.g. PFA or others to keep the wafers plane in the single side etching process. Possible is also an optimized ingot orientation at the squaring process, or optimized brick orientation in the case of quasi-mono. This kind of orientation optimization needs to consider also the mechanical strength of the resulting wafer as cut.

In various embodiments, an acidic etching step on the at least one surface of the Si wafer as cut may be conducted several times. The etching step may be conducted on one surface more often than on the other side, e.g. on one side twice and on the other side once.

In various embodiments of the present invention the etching process described herein is performed on at least one surface of a Si wafer and during later processing of the wafer, the same or different surface may be subjected to a further etching process, such as a texture etching process.

In various embodiments of the present invention, the method further comprises generating a passivation layer on one surface of the Si wafer after the etching process. This passivation layer may for example be a SiO₂/SiNₓ passivation layer or an Al₂O₃/SiNₓ passivation layer. The term “generating a passivation layer” as used herein refers to making, producing, forming, modeling, depositing, immobilizing and attaching such passivation layer on the wafer surface. This may achieved by known techniques like quartz furnace processes—dry or wet, different processes of chemical vapor depositions like CVD, PECVD, atomic layer depositions (ALD), also plasma assisted, also by processes of physical depositions like sputtering, electron beam evaporating, molecular beam epitaxy, cathodic arc depositions.

Further applicable techniques might also include printing, melting, sintering, dip coating and spary-coating all of which are well known in the art. Other suitable techniques also known in the art may similarly be used. When using the acidic etching process claimed herein, a surface polishing step for the passivation layer stack as known in the art may not be necessary anymore.

In further embodiments of the present invention the method further comprises an alkaline etching process, preferably an alkaline texture etching process, that is conducted after the acidic etching of the at least one Si wafer surface, and done optionally either straight after generating the passivation layer, or after the rear side laser ablation process to texturize additional the ablated rearside pattern in the passivation layer. The passivation layer for example may be a SiO₂/SiNₓ passivation layer or an Al₂O₃/SiNₓ passivation layer on one surface of the Si wafer. A surface polishing step for the passivation layer stack is not necessary as already described above. In various embodiments, the passivation layer is generated on the rear surface of the wafer and the texture etching is performed on the front surface of the wafer.

The subsequent alkaline etching process refers to commonly known alkaline etching processes and may be conducted with an alkaline etching agent known in the art. Such an alkaline etching agent may for example and without limitation be selected from the group consisting of sodium hydroxide, potassium hydroxide, potassium carbonate, sodium carbonate, calcium hydroxide, and mixtures thereof In a further embodiment, the alkaline etching agent is sodium hydroxide or potassium hydroxide, preferably potassium hydroxide. Such agents are the most commonly used etching agents in texturisation processes. State of the art is the requirement of additional components e.g. isopropanol, or cyclohexandiols, certain surfactants, polysaccharides or other more. Organic etching agents like tetramethylammonium hydroxide and ethylenediamine pyrocatechol require longer treatment times to achieve a similar etching, but they have the effect not to provide metallic cations.

In various embodiments, the method may further comprise a doping step, wherein the Si wafer is doped with elements known in the art in order to modulate the electrical properties of the wafer. Such an element may for example be phosphor or boron.

In various embodiments, the method may remove the phosphorous glass straight after the phosphorous diffusion, forming the selective emitter after the front-side AR- and passivation process, and then continue with the rear-side local pattering.

In various embodiments, the acidic etching process may be carried out as an in-line process or as a batch process. In a preferred embodiment, the etching process of the present invention is part of an in-line process.

In various embodiments, the following texture etching process may be carried out as an in-line process or as a batch process. In a preferred embodiment, the etching process of the present invention is part of a batch process

The Si wafer produced according to the processes described herein may form part of a photovoltaic cell, preferably a PERC cell. Such a photovoltaic or solar cell also forms part of the present invention. Also encompassed by the present invention are solar modules containing a solar cell according to the present invention.

### EXAMPLES

### Example 1

Monocrystalline wafers obtained by the Czochralski process were contacted with a mixture of AcOH (98 wt.-% in water), HNO₃ (69 wt.-% in water), and HF (49 wt.-% in water) as acidic etching agent. The volume ratio of AcOH:HNO₃:HF was 10:6:4. The wafers were compared with reference wafers that were processed through the alkaline saw damage etch process, achieving polished surfaces. The quality of the deposited passivation stack was measured comparing the life time and implied Voc in so called “Quasi Tau Samples” using the Sinton photoconductance method that is used for process quality control. Said wafer had a thickness of about 160 μm and were measured at a carrier density of 1E+15. The measured life time was 182 μsec in average for the acidic etched samples, resulting in an implied voltage of 678 mV, while result of the reference samples was 172 μsec in average and also 678 mV.

### Example 2

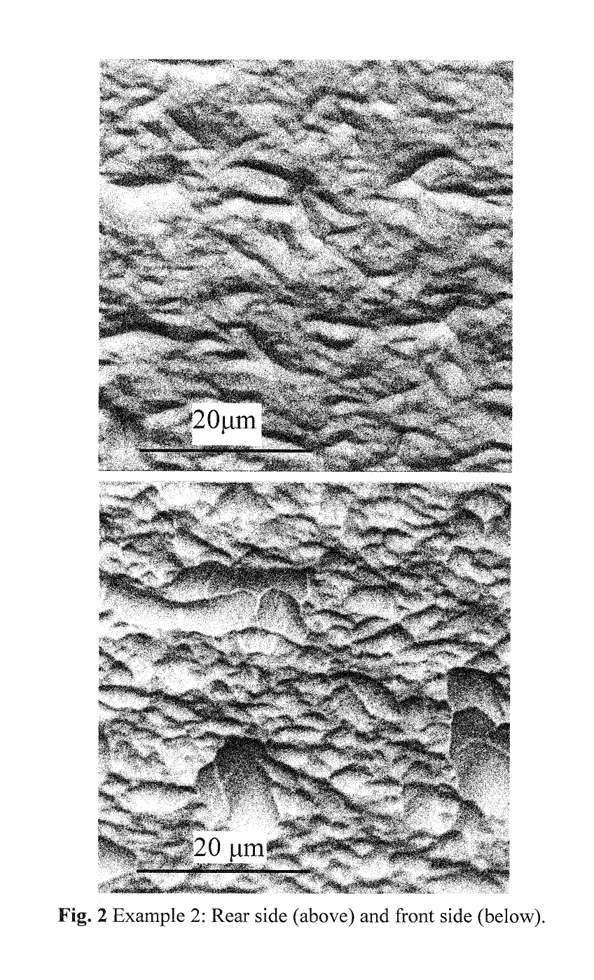

The rear side of monocrystalline Si wafer as cut were contacted with a mixture of HNO₃ (67.5 wt.-% in water) and HF (49 wt.-% in water) for 3 minutes at 15 ° C. The volume ratio of HNO₃ HF was 6.5:1 and a Si removal of 9.5 μm was obtained. FIG. 2 shows a SEM image of a rear side of a monocrystalline Si wafer treated with said mixture under the above conditions.

### Example 3

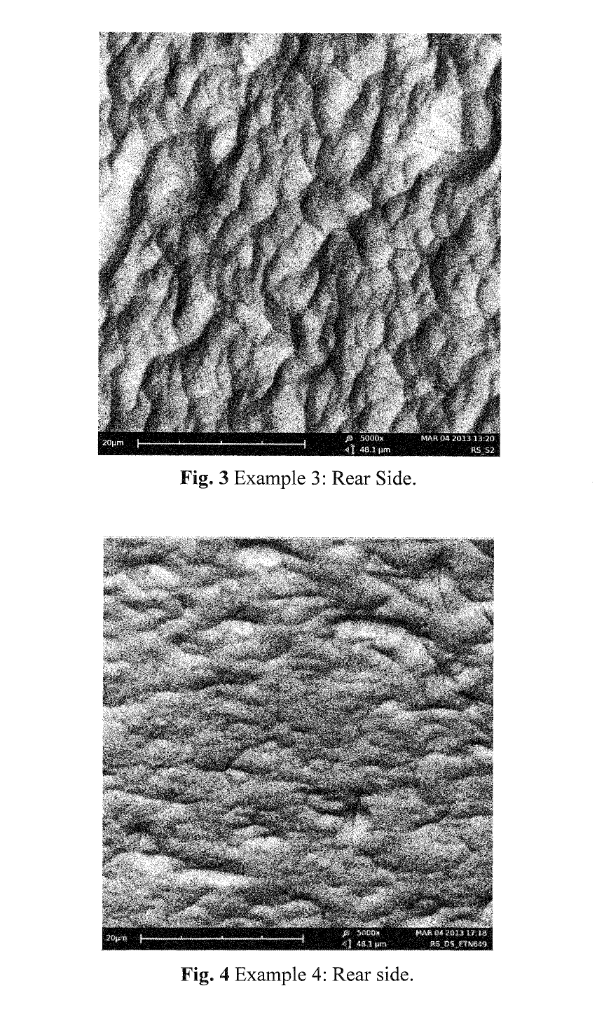

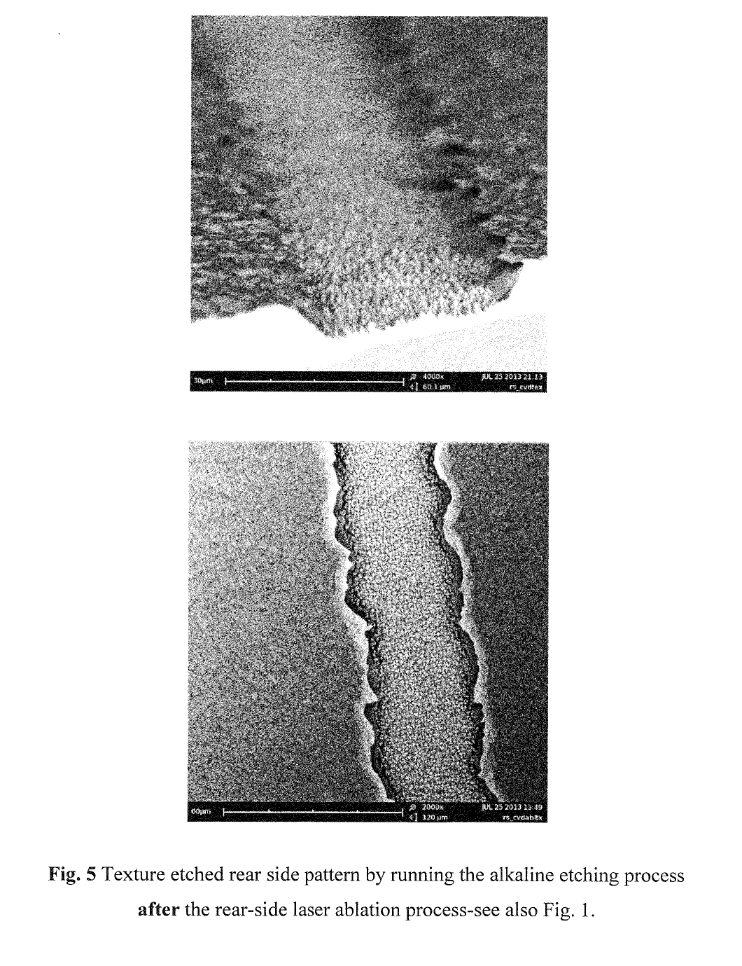

The rear side of a monocrystalline Si wafer as cut were contacted for 3 minutes at 12° C. with a mixture of HNO3 (69.5 wt.-% in water) and HF (49 wt.-% in water). The volume ratio of HNO₃:HF was 9:1 and a Si removal of 7 μm was obtained. FIG. 3 shows a SEM image of a rear side of a monocrystalline Si wafer treated with said mixture under the above conditions.

### Example 4

Monocrystalline insufficiently cleaned stained wafers obtained by the Czochralski process were contacted with a mixture HNO₃ (69 wt.-% in water) and HF (49 wt.-% in water) as acidic etching agent at 15-20° C. temperature. The volume ratio of HNO₃: HF was 8:1. The total etch removal was 17-20 μm. The median cell-efficiency was 19.56%. This value was determined on the basis of test runs with about 3300 wafers. The wafers were exposed for about 4 minutes in the acidic etching solution. FIG. 4 shows a SEM image of a rear side of a monocrystalline Si wafer treated with said mixture under the above conditions.

While particular preferred and alternative embodiments of the present intention have been disclosed, it will be apparent to one of ordinary skill in the art that many various modifications and extensions of the above described technology may be implemented using the teaching of this invention described herein. All such modifications and extensions are intended to be included within the true spirit and scope of the invention as discussed in the appended claims.

1. A method for acidic etching of a Si wafer, comprising contacting at least one surface of a Si wafer as cut with an acidic etching agent with the proviso that the Si wafer is, prior to the acidic etching, not subjected to an alkaline etching step or process.

2. The method according to claim 1, wherein the Si wafer is a monocrystalline or a quasi-monocrystalline Si wafer.

3. The method according to claim 1, wherein the Si wafer is saw-damaged and/or cleaned prior to etching.

4. The method according to claim 1, wherein the acidic etching agent is an aqueous solution of an acid selected from the group consisting of HF, HCl, HBr, HI, AcOH, HNO₃, H₃PO₄, H₂SO₄, citric acid, oxalic acid, lactic acid and mixtures Thereof.

5. The method according to claim 1, wherein the acid etching agent is an aqueous solution containing a mixture of AcOH, HNO₃ and HF.

6. The method according to claim 5, wherein the solution comprises AcOH (98 wt.-% in water), HNO3 (69 wt.-% in water), and HF (49 wt.-% in water), wherein the volume ratio of AcOH:HNO₃:HF is 10:6:4.

7. The method according to claim 1, wherein the acid etching agent is a mixture of HNO₃ and HF.

8. The method according to claim 7, wherein the mixture consists of HNO₃ (67-70 wt.-% in water) and HF (49 wt.-% in water), wherein the volume ratio of HNO₃:HF gradually changes over time from about 6:1 to 10:1 at the start to a final volume ratio of 2:1 to 1.2:1

9. The method according to claims 1 to 8, wherein the acidic etching agent is contacted with at least one surface of the Si wafer as cut once or several times.

10. The method according to claim 1, wherein the step of contacting an acid etching agent with at least one surface of the Si wafer comprises dipping, spraying, coating or printing.

11. The method according to claim 1, wherein the method further comprises generating a SiO₂/SiNₓ passivation layer or an Al₂O₃/SiNₓ passivation layer on one surface of the Si wafer after the acidic etching process.

12. The method according to claim 1, wherein the method further comprises an alkaline etching process, preferably an alkaline texture etching process, conducted after the acidic etching of the at least one Si wafer surface and optionally after generating the SiO₂/SiNₓ passivation layer or Al₂O₃/SiNₓ passivation layer on one surface of the Si wafer, or optionally after the laser ablation process to texture etch the front surface and the ablated pattern at the wafer rear-side.

13. The method according to claim 1, wherein the method further comprises the steps of:
doping the Si wafer with phosphorus in order to modulate the electrical properties of the wafer.

14. The method according to claim 1, wherein the method is a part of an in-line process.

15. Si wafer obtainable accordingly to the method of claim 1.

16. Solar cell comprising the Si wafer of claim 14.

17. Solar module comprising a solar cell according to claim 15.
